(19) United States
(12) Patent Application Publication
(10) Pub. No.: US 2003/0173027 A1
(43) Pub. Date: Sep. 18, 2003

(54) Deposit removing apparatus and deposit removing method

(75) Inventor: Seiji Sano, Kasugai (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/378,608

(22) Filed: Mar. 5, 2003

(30) Foreign Application Priority Data
Mar. 15, 2002 (JP) 2002-072743

(51) Int. Cl. H01L 21/306

(52) U.S. Cl. 156/345.21; 156/345.18; 156/345.55; 216/83; 216/93

(57) ABSTRACT

Deposit is removed by supplying chemical solution on a semiconductor substrate with the semiconductor substrate kept rotating. Next, the chemical solution supply is shut off while rotation of the semiconductor substrate being maintained, which allows to scatter the chemical solution on the semiconductor substrate. Next, water is supplied on the semiconductor substrate with the semiconductor substrate kept rotating. This results in washing the semiconductor substrate. The water supply is shut off while rotation of the semiconductor substrate being maintained, which allows to scatter the water on the semiconductor substrate. Then, these processes are repeated depending on a degree of cleanness on a front face of the semiconductor substrate. In this removing method, the chemical solution and the water are hardly mixed so as to prevent corrosion and elution of a wiring material.

### CROSS-REFERENCE TO RELATED APPLICATIONS

This application is based upon and claims the benefit of priority from the prior Japanese Patent Application No. 2002-072743, filed on Mar. 15, 2002, the entire contents of which are incorporated herein by reference.

### BACKGROUND OF THE INVENTION

1. Field of the Invention

The present invention relates to a deposit removing apparatus and a deposit removing method, in which deposit that is deposited on a semiconductor substrate during etching of a thin film formed on the semiconductor substrate is removed with the use of fluorinated chemical solution or the like.

2. Description of the Related Art

Microchip fabrication includes an etching process, the etching process including to form on the semiconductor substrate: a metal film such as aluminum or copper; or an insulating film such as a silicon oxide film or a silicon nitrided film, and to perform etching of the film using a resist film applied thereon as a mask, so as to develop a certain pattern. In this etching process, in a case of forming a fine circuit pattern, dry ethching such as reactive ion ethching (RIE: Reactive Ion Etching) is mainly employed.

Since a reactive ion used in this reactive ion etching has extremely great energy, etching of a metal film or an insulating film involves progress in removing a resist film being a mask. Then, after a removed substance of the resist film changes its nature to a reaction product such as a high molecular compound or the like, the removed substance deposits along side walls of the patterned metal film or the patterned insulating film. This causes unnecessary deposit to exist along the side walls of the metal film or the insulating film at the instant of completing the etching of the metal film or the insulating film. The deposit comprising this reaction product cannot be removed in a resist film removing process to be performed thereafter. Therefore, it is necessary to remove the reaction product before the resist film removing process.

Conventionally, such a method is employed to remove the reaction product, namely, deposit as to supply chemical solution that operates to remove the reaction product onto the substrate after the dry etching. When the removal process of the reaction product is completed, a process to wash the substrate with water is performed.

In a condition where the chemical solution and the water coexist, though it depends on a pH value of the mixed liquid, there is a chance that an exposed portion of the metal film may be corroded or a metal film material may be eluted. Therefore, such a method is employed that after the deposit is removed by using the chemical solution, an organic solvent or the like is supplied on the substrate to remove the chemical solution, and thereafter washing in the water is performed.

This involves a problem that performing such a process as to supply the organic solvent or the like on the substrate prior to a washing process in which the water is used prolongs a processing time, which results in lowering processing ability. There is also a problem that using the organic solvent requires explosion-proof measures in a apparatus and this increases apparatus cost.

### SUMMARY OF THE INVENTION

The present invention is made in light of these disadvantages and an object thereof is to provide a deposit removing apparatus and a deposit removing method that enable to suppress an increase in apparatus cost as well as to improve throughput.

Inventors of this application reach various aspects of this invention as shown below after their committed studies.

A deposit removing apparatus according to the present invention is for deposited material on a semiconductor substrate during etching of a film formed on the semiconductor substrate. This deposit removing apparatus includes: a chuck for fixing the semiconductor substrate; a rotator for rotating the chuck with its rotating axis being perpendicular to a surface of the semiconductor substrate; a chemical solution tube for supplying chemical solution, which function as to exfoliate the deposit from the semiconductor substrate, onto a position spaced from a plane surface center of the semiconductor substrate, so that the chemical solution can reach the plane surface center of the semiconductor substrate; and a rinsing water tube for supplying water onto a position spaced from the plane surface center of the semiconductor substrate, so that the water can reach the plane surface center of the semiconductor substrate.

In the present invention, the chemical solution and the water are supplied on the semiconductor substrate from the chemical solution tube and the rinsing water tube, respectively. The chemical solution and the water are so supplied onto a position spaced from a plane surface center of the semiconductor substrate as that the chemical solution and the water can reach the plane surface center of the semiconductor substrate. Therefore, rotation of the semiconductor substrate involves the chemical solution and the water to wettingly extend therefrom to the entire semiconductor substrate. Then, after shutting off the supply of each liquid, the chuck is caused to rotate by the rotator. This involves the rotation of the semiconductor substrate so that a centrifugal force operates to scatter each liquid from the semiconductor substrate. Therefore, the chemical solution and the water have little chance to be mixed, which enables to prevent corrosion and elution of a wiring material without using an organic solvent.

A deposit removing method according to the present invention is for deposited material on the semiconductor substrate during etching of a film formed on the semiconductor substrate. This deposit removing method includes the steps of: supplying chemical solution on the semiconductor substrate to exfoliate the deposit from the semiconductor substrate; scattering the chemical solution by rotating the semiconductor substrate; and supplying water on the semiconductor substrate.

### BRIEF DESCRIPTION OF THE DRAWINGS

FIG. 1 is a plan view showing a structure of a deposit removing apparatus according to an embodiment of the present invention;

FIG. 2 is a sectional view showing a structure of the deposit removing apparatus according to the embodiment of the present invention;

FIG. 3 is a sectional view showing a processing material in which deposit is deposited on a semiconductor substrate;

FIG. 4 is a flow chart showing a first embodiment of a deposit removing method;

FIG. 5 is a flow chart showing a second embodiment of the deposit removing method, and

FIGS. 6A to 6D are micrographs showing results of each of examples and comparative examples.

### DETAILED DESCRIPTION OF THE PREFERRED EMBODIMENTS

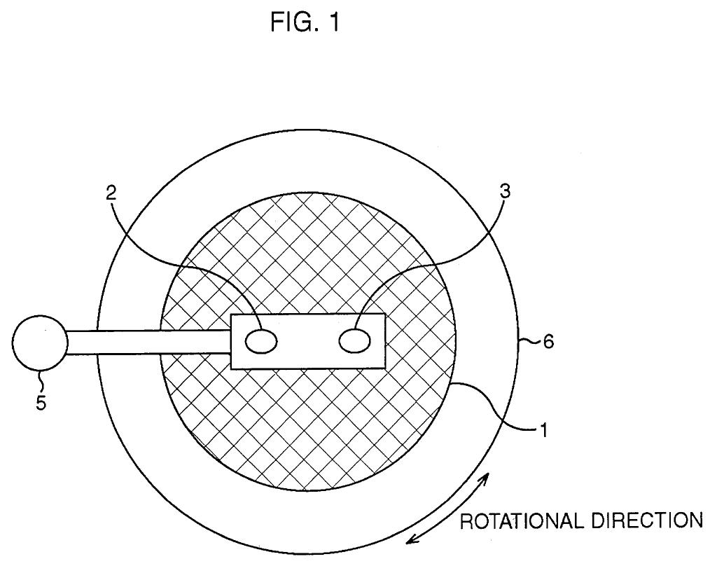

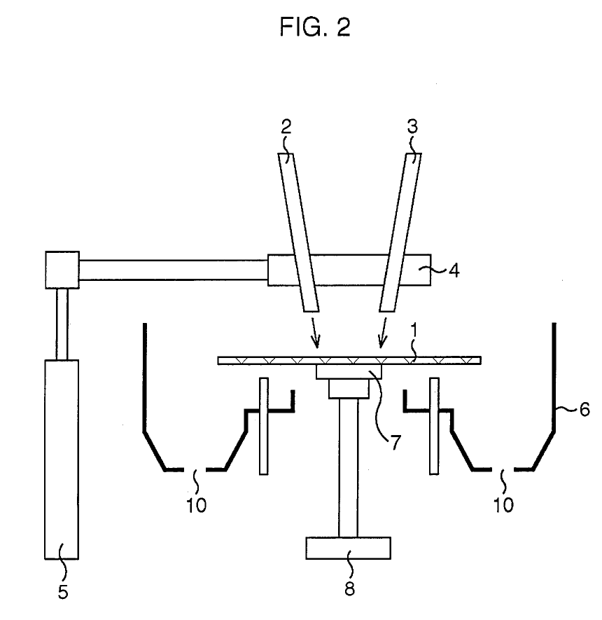

Hereinafter, a deposit removing apparatus and a deposit removing method according to embodiments of the present invention will be described in detail with reference to the attached drawings. FIG. 1 and FIG. 2 are a plan view and a sectional view respectively, showing a structure of the deposit removing apparatus according to an embodiment of the present invention.

The removing apparatus relating to this embodiment comprises a spin chuck (fixing chuck) 7 for fixing a semiconductor substrate (wafer) 1 at its back side by, for example, adsorption, and a motor 8 for rotating the spin chuck 7 with its rotating axis perpendicular to a surface of the semiconductor substrate 1. A chemical solution tube 2 and a rinsing water tube 3, which supply chemical solution and water onto the front face of the semiconductor substrate 1 respectively, are arranged to face the spin chuck 7. The chemical solution tube 2 and the rinsing water tube 3 are held by a tube holding portion 4 being provided at a tip portion of a tube moving mechanism 5. The chemical solution and the water flowing out from the chemical solution tube 2 and the rinsing water tube 3 are, for example, supplied into a direction sloping against a direction perpendicular to the front face of the semiconductor substrate 1. The chemical solution tube 2 and the rinsing water tube 3 are so held by the tube holding portion 4 that an interval between the tip portions thereof and the semiconductor substrate 1 lies within, for example, about 10 to 20 mm. The chemical solution tube 2 and the rinsing water tube 3 are made possible to be moved by the tube moving mechanism 5 between a neighboring position directly above a plane surface center on the semiconductor substrate 1 being fixed by the spin chuck 7, and a position spaced from a peripheral edge of the semiconductor substrate 1. To the other ends of the chemical solution tube 2 and the rinsing water tube 3, a chemical-solution-supplying portion and a water-supplying portion are connected, respectively.

A composition of the chemical solution supplied from the chemical solution tube 2 is not intended to be limiting in particular, as long as it can remove such deposit as a reaction product, the deposit being deposited on the semiconductor substrate 1 during etching of such a film as a metal film or an insulating film being formed on the semiconductor substrate 1. For example, it is possible to use such liquid as (1) liquid including organic alkali liquid such as dimethylformaldehyde (DMF), dimethyl sulfoxide (DMSO) or hydroxylamine, (2) liquid including an inorganic acid such as a hydrofluoric acid or a phosphoric acid, or (3) liquid including ammonium fluoride-related substance. Such liquid may also be used as to include 1-methyl-2 pyrrolidone, tetrahydrothiophene 1. 1-dioxide, isopropanolamine, monoethanolamine, 2-(2 amino ethoxy) ethanol, catechol, N-methylpyrrolidone, aromatic diol, or phenol. To be more precise, the followings can be used: (a) a mixed liquid of 1-methyl-2 pyrrolidone, tetrahydrothiophene 1. 1-dioxide, and isopropanolamine; (b) a mixed liquid of dimethyl sulfoxide and monoethanolamine; (c) a mixed liquid of 2-(2 amino ethoxy) ethanol, hydroxylamine, and catechol; (d) a mixed liquid of 2-(2 amino ethoxy) ethanol and N-methylpyrrolidone, (e) a mixed liquid of monoethanolamine, water, and aromatic diol; (f) a mixed liquid containing phenol; and the like.

There is provided a scattering prevention cup 6 surrounding the circumference of the spin chuck 7 and its under-area to collect the chemical solution and the water that are scattered from the front face of the semiconductor substrate 1. A plane shape of the scattering prevention cup 6 is formed to be substantially ring-shaped, that is, an opening through which a shaft passes to transmit a driving force of the motor 8 to the spin chuck 7 is formed on the center part thereof. At the bottom of the scattering prevention cup 6, openings 10 are formed to discharge liquid collected in the scattering prevention cup 6. Drains (not shown) are connected to the openings 10. Additionally, back face washing tubes 9 are arranged with certain intervals from the spin chuck 7 to supply water on a back face of the semiconductor substrate 1. Tip portions of the back face washing tubes 9 are arranged, for example, within the scattering prevention cup 6 so that the water dropped from the back face of the semiconductor substrate 1 after washing can be collected in the scattering prevention cup 6.

Although the removing apparatus employs a sheet-fed type, it is to be understood that the present invention is not intended to be limited to this type.

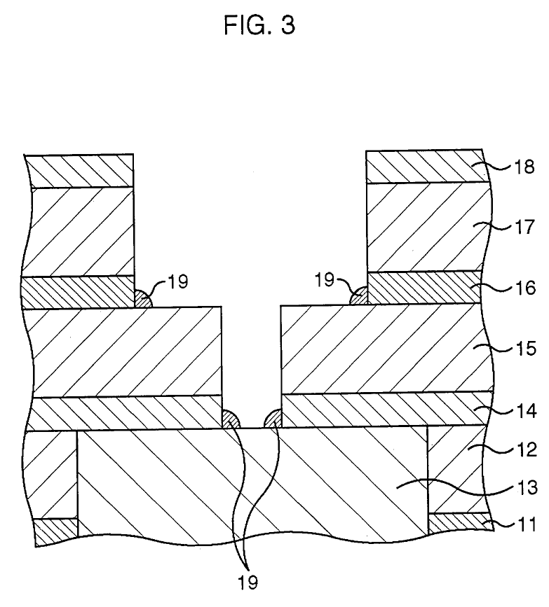

Next described is how to use the above-described removing apparatus, namely, a deposit removing method with the use of the removing apparatus. FIG. 3 is a sectional view showing a processing material in which deposit is deposited on the semiconductor substrate.

This processing material comprises a damascene structure. Specifically, a trench is formed in an organic insulating film 11 and an USG (Undoped Silicate Glass) film 12 that are formed on the semiconductor substrate (not shown), and a wiring material 13 is buried in this trench. On the upper layers thereof, there are sequentially formed a silicon nitrided film 14, an USG film 15, an organic insulating film 16, an USG film 17, and a silicon nitrided film 18. Then, a trench for wiring is formed in the organic insulating film 16, the USG film 17, and the silicon nitrided film 18, while a hole for connecting between wires is formed in the silicon nitrided film 14 and the USG film 15. In the bottom corners of the trenches for wiring and the hole, there exists deposit 19 formed by deposition of the reaction products generated by etching of resist films (not shown) that are used to form these trench and hole.

First Embodiment of Deposit Removing Method

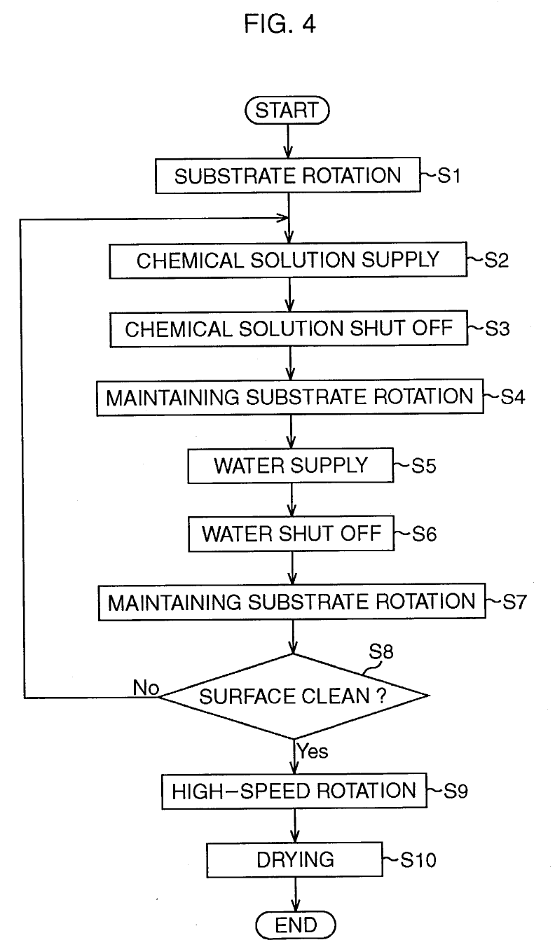

First, a first embodiment of a deposit removing method will be described. FIG. 4 is a flow chart showing the first embodiment of the deposit removing method. In this embodiment, first, the semiconductor substrate 1 is fixed by the spin chuck 7, and thereafter the motor 8 rotates the spin chuck 7 and the semiconductor substrate 1 (step S1). Here, the rotation speed is, for example, from 100 to 1000 rotations/minute.

Next, a position of the chemical solution tube 2 is adjusted by the tube moving mechanism 5 with the semiconductor substrate 1 kept rotating, so that a plane surface center of the semiconductor substrate 1 is included in a discharge area of the chemical solution. Thereafter, the chemical solution is supplied from the chemical solution tube 2 onto the semiconductor substrate 1 only for a previously set period (step S2). Here, the supply rate is, for example, from 200 to 1000 ml/minute. As a result, the chemical solution is supplied at least on the plane surface center of the semiconductor substrate 1, and then wettingly extend therefrom to the entire semiconductor substrate 1 by a centrifugal force.

Next, the chemical solution supply is shut off (step S3). Then, rotation of the spin chuck 7 and the semiconductor substrate 1, caused by the motor 8, is maintained, for example, for 0.1 to 30 seconds (step S4). Here, the rotation speed is, for example, from 100 to 1000 rotations/minute. As a result, the chemical solution that is supplied in the step S2 are scattered to the circumference of the semiconductor substrate 1 by the centrifugal force, so that the chemical solution on the semiconductor substrate 1 significantly decreases in quantity. The chemical solution scattered to the circumference of the semiconductor substrate 1 is collected in the scattering prevention cup 6.

Next, a position of the rinsing water tube 3 is adjusted by the tube moving mechanism 5 with the semiconductor substrate 1 kept rotating, so that a plane surface center of the semiconductor substrate 1 is included in a discharge area of the water. Thereafter, the water is supplied from the rinsing water tube 3 onto the semiconductor substrate 1 only for a previously set period (step S5). Here, the supply rate is, for example, from 200 to 1000 ml/minute. As a result, the water is supplied at least on the plane surface center of the semiconductor substrate 1, and then wettingly extends therefrom to the entire semiconductor substrate 1 by the centrifugal force. This causes substantially full removal of residual chemical solution on the semiconductor substrate 1. Additionally, the water is supplied from the back face washing tubes 9 onto the back face of the semiconductor substrate 1, while the water is supplied from the rinsing water tube 3. Note that in a case when position adjustment of the chemical solution tube 2 results in adjusting the position of the rinsing water tube 3 to an appropriate position, the readjustment is not needed.

Next, the water supply is shut off (step S6). Then, rotation of the spin chuck 7 and the semiconductor substrate 1, caused by the motor 8, is maintained, for example, for 0.1 to 30 seconds (step S7). Here, the rotation speed is, for example, from 100 to 1000 rotations/minute. As a result, the water that is supplied in the step S5 is scattered to the circumference of the semiconductor substrate 1 by the centrifugal force, so that the water on the semiconductor substrate 1 significantly decreases in quantity. The water scattered to the circumference of the semiconductor substrate 1 is collected in the scattering prevention cup 6.

Then, whether the deposit is fully removed to have a clean surface or not is confirmed (step S8). In a case when the surface is not cleaned, processes from the step S2 to the step S8 are repeated.

On the other hand, in a case when the surface is confirmed to be clean in the step S8, the spin chuck 7 and the semiconductor substrate 1 are rotated much faster by the motor 8 (step S9). Here, the rotation speed is, for example, from 1000 to 5000 rotations/minute. This causes almost all the water on the semiconductor substrate 1 to vanish. The water scattered to the circumference of the semiconductor substrate 1 is collected in the scattering prevention cup 6.

Next, the semiconductor substrate 1 is removed from the spin chuck 7 and dried (step S10). The deposit removal ends with the above processes.

The liquid collected in the scattering prevention cup 6 may be discharged from the openings 10, for example, after the semiconductor substrate 1 is removed from the spin chuck 7.

According to the first embodiment of the deposit removing method, there is very little time for the chemical solution and the water to be mixed. Therefore, corrosion of the wiring material 13 being a metal film may hardly occur and elution of material in the wiring material 13 may hardly occur as well. In addition, no need to use an organic solvent can avoid the apparatus becoming complicated and costly and avoiding an increase in the number of processes causes to improve throughput. Further, the operation of the chemical solution enables to fully remove the deposit 19.

### Second Embodiment of Deposit Removing Method

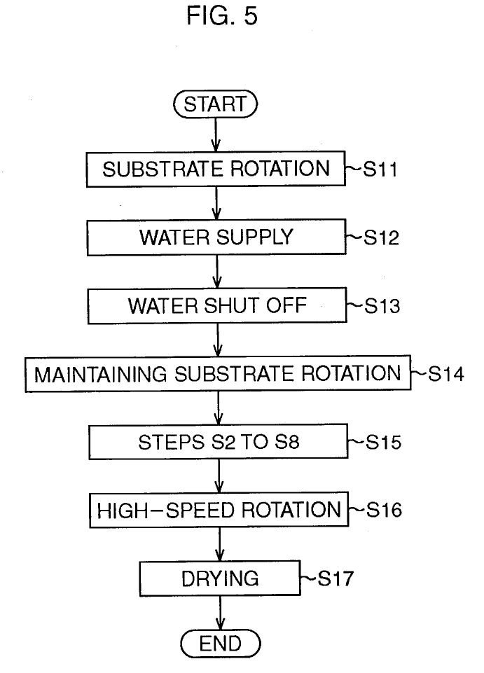

Secondly, a second embodiment of a deposit removing method will be described. FIG. 5 is a flow chart showing the second embodiment of the deposit removing method. In this embodiment as well, first, the semiconductor substrate 1 is fixed by the spin chuck 7, and thereafter the motor 8 rotates the spin chuck 7 and the semiconductor substrate 1 (step S11). Here, the rotation speed is, for example, from 100 to 1000 rotations/minute.

Next, a position of the rinsing water tube 3 is adjusted by the tube moving mechanism 5 with the semiconductor substrate 1 kept rotating, so that a plane surface center of the semiconductor substrate 1 is included in a discharge area of the water. Thereafter, the water is supplied from the rinsing water tube 3 on the semiconductor substrate 1 only for a previously set period (step S12). Here, the supply rate is, for example, from 200 to 1000 ml/minute. As a result, the water is supplied at least on the plane surface center of the semiconductor substrate 1, and then wettingly extends therefrom to the entire semiconductor substrate 1 by a centrifugal force. Additionally, the water is supplied from the back face washing tubes 9 onto the back face of the semiconductor substrate 1, while the water is supplied from the rinsing water tube 3.

Next, the water supply is shut off (step S13). Then, rotation of the spin chuck 7 and the semiconductor substrate 1, caused by the motor 8, is maintained, for example, for 0.1 to 30 seconds (step S14). Here, the rotation speed is, for example, from 100 to 1000 rotations/minute. As a result, the water that is supplied in the step S13 is scattered to the circumference of the semiconductor substrate 1 by the centrifugal force, so that the water on the semiconductor substrate 1 significantly decreases in quantity. The water scattered to the circumference of the semiconductor substrate 1 is collected in the scattering prevention cup 6.

Next, processes from the step S2 to the step S8 in the first embodiment are performed. In this embodiment, a period for maintaining the rotation in the step S4 and the step S7 is set to, for example, from 0.1 to 30 seconds.

Then, in a case when the surface is confirmed to be clean in the step S8, the spin chuck 7 and the semiconductor substrate 1 are rotated much faster by the motor 8 (step S16). Here, the rotation speed is, for example, from 1000 to 5000 rotations/minute. This causes almost all the water on the semiconductor substrate 1 to vanish. The water scattered to the circumference of the semiconductor substrate 1 is collected in the scattering prevention cup 6.

Next, the semiconductor substrate 1 is removed from the spin chuck 7 and dried (step S17). The deposit removal ends with the above processes.

The liquid collected in the scattering prevention cup 6 may be discharged from the openings 10, for example, after the semiconductor substrate 1 is removed from the spin chuck 7.

According to the second embodiment of the deposit removing method, the same effect as in the first embodiment can be obtained and the water supply and its removal is performed before supplying the chemical solution, which allows to further facilitate exfoliation of the deposit 19 when the chemical solution is supplied thereafter. This enables to fully remove the deposit 19 even with the less number of times to repeat the processes from the step S2 to the step S8. This results in a reduced quantity of the chemical solution to be consumed and a decrease in the number of processes causes to further improve processing ability (throughput).

Note that nozzles may be connected to the tips of the tubes.

It is to be understood that a film formed and patterned on the semiconductor substrate is not intended to be limited to a certain kind. For example, a metal film such as a Cu film, an Al film, or a W-film, or an insulating film such as a silicon oxide film or a silicon nitrided film may be formed on the semiconductor substrate as a patterned film.

Further, the present invention may be applied to deposit produced during dry etching that uses a hard mask.

In addition, it is to be understood that a structure of the semiconductor device to which the present invention may be applicable is not limited to the damascene structure.

In both of the first and second embodiments, a repeat count of the processes from the step S2 to the step S8 is not to fluctuate in a great deal if such main conditions as processing temperature, a diameter of the semiconductor substrate, and supply rate of the chemical solution and the water are maintained constant. Therefore, when the repeat count is previously set depending on the conditions, determination in the step S8 may be made by confirming whether the predetermined repeat count is executed, instead of determining whether the surface is cleaned or not.

### EXAMPLE

Next, an example of the present invention will be described in comparison with a comparative example that departs from a scope of the present invention.

First, a specimen is formed in which a first barrier metal film composed of a Ti film and a TiN film, an Al film, a second barrier metal film composed of a Ti film and a TiN film, and a silicon nitrided film are sequentially formed on an insulating film formed on a semiconductor substrate. Next, a trench is formed in the first barrier metal film, the Al film, the second barrier metal film, and the silicon nitrided film by performing dry etching using a resist film applied thereon as a mask. Here, reaction products generated by the etching of the resist film are deposited in the trench as deposit.

Next, the followings attempted are various methods to remove the deposit.

In one example No. 1, deposit removal was attempted based on the aforementioned first embodiment. Here, a supply time of the chemical solution, a flow rate of the chemical solution, temperature of the chemical solution, and rotation speed of the substrate in the step S2 were set to 15 seconds, 600 ml/minute, 30° C., and 200 rotations/minute, respectively. A period for maintaining the rotation in the step S4 was set to 5 seconds, while a supply time of the water, a flow rate of the water, temperature of the water, and rotation speed of the substrate in the step S5 were set to 30 seconds, 600 ml/minute, standard temperature, and 500 rotations/minute, respectively. A period for maintaining the rotation in the step S7 was set to 5 seconds. In addition, processes from the step S2 to the step S8 were repeated twice.

In another example No. 2, the deposit removal was attempted based on the aforementioned second embodiment. Here, a supply time of the water, a flow rate of the water, temperature of the water, and rotation speed of the substrate in the step S12 were set to 30 seconds, 600 ml/minute, normal temperature, and 500 rotations/minute, respectively. A period for maintaining the rotation in the step S14 was set to 5 seconds, while a supply time of the chemical solution, a flow rate of the chemical solution, temperature of the chemical solution, and rotation speed of the substrate in the step S2 were set to 15 seconds, 600 ml/minute, 30° C., and 200 rotations/minute, respectively. A period for maintaining the rotation in the step S4 was set to 5 seconds, while a supply time of the water, a flow rate of the water, temperature of the water, and rotation speed of the substrate in the step S5 were set to 30 seconds, 600 ml/minute, standard temperature, and 500 rotations/minute, respectively. A period for maintaining the rotation in the step S7 was set to 5 seconds. In addition, processes from the step S2 to the step S8 were performed only once.

One comparative example No. 3 employed such an attempt to remove the deposit as that first the chemical solution was supplied on the semiconductor substrate for 60 seconds, and then, the water was further supplied on the semiconductor substrate for 30 seconds with the chemical solution still remaining on the semiconductor substrate, to thereafter make it dried.

Another comparative example No. 4 employed such an attempt to remove the deposit as to twice repeat the chemical solution supply on the semiconductor substrate for 15 seconds and the water supply on the semiconductor substrate for 30 seconds with the chemical solution still remaining on the semiconductor substrate, and thereafter to make it dried.

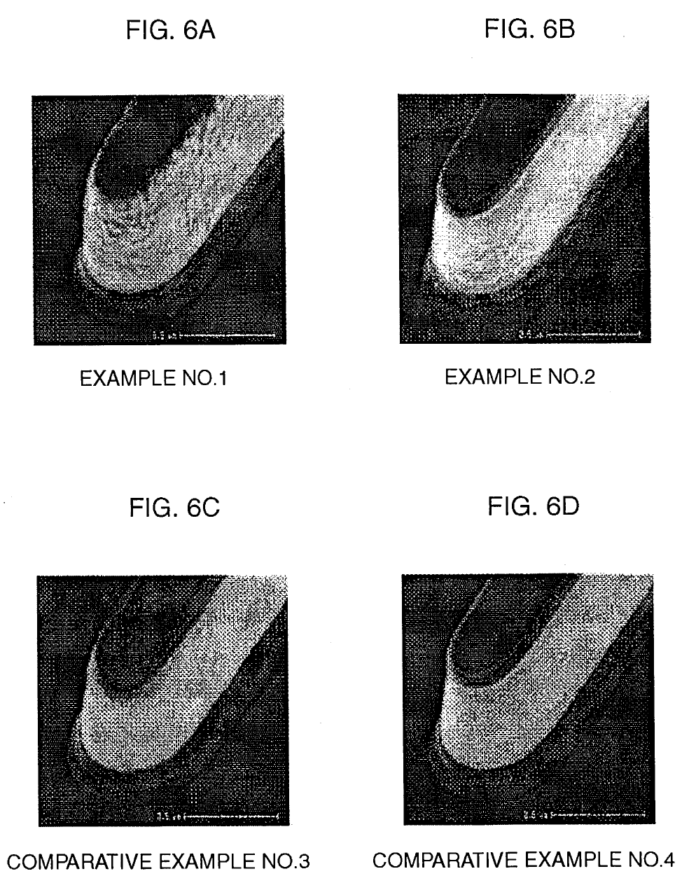

FIGS. 6A to 6D are micrographs showing results of each of the examples and comparative examples. The examples No. 1 and No. 2, as shown in FIGS. 6A and 6B respectively, enabled to remove the deposit as well as to prevent elution from the Ti film and the TiN film. The example No. 2, in particular, performed water washing in the first place so that it was not necessary to repeat the processes from the step S2 to the step S8, which allowed to shorten a processing time with the use of the chemical solution. On the other hand, the comparative example No. 3 could not fully remove the chemical solution. The comparative example No. 4 could remove the deposit, but it resulted in producing the elution from the Ti film and the TiN film constituting the barrier metal film.

As described above, the present invention rotates the semiconductor substrate after the chemical solution and the water are supplied, so that the liquids are scattered and prevented from being mixed with each other. Therefore, corrosion and elution of a wiring material can be prevented without using an organic solvent, which enables to suppress an increase in apparatus cost as well as to improve processing ability (throughput).

The present embodiments are to be considered in all respects as illustrative and no restrictive, and all changes which come within the meaning and range of equivalency of the claims are therefore intended to be embraced therein. The invention may be embodied in other specific forms without departing from the spirit or essential characteristics thereof.

Hereinafter, various aspects of the present invention will be described as claims.

What is claimed is:

1. A deposit removing apparatus for deposited material on a semiconductor substrate during etching of a film formed on said semiconductor substrate, comprising:
a chuck for fixing said semiconductor substrate;
a rotator for rotating said chuck with its rotating axis being perpendicular to a surface of said semiconductor substrate;
a chemical solution tube for supplying chemical solution, which function as to exfoliate said deposit from said semiconductor substrate, onto a position spaced from a plane surface center of said semiconductor substrate, so that said chemical solution reaches the plane surface center of said semiconductor substrate; and
a rinsing water tube for supplying water onto a position spaced from the plane surface center of said semiconductor substrate, so that said water reaches the plane surface center of said semiconductor substrate.

2. The deposit removing apparatus according to claim 1, wherein said chuck fixes said semiconductor substrate by adsorption.

3. The deposit removing apparatus according to claim 1, further comprising a back face washing tube supplying said water onto a back face of said semiconductor substrate being fixed on said chuck.

4. The deposit removing apparatus according to claim 1, further comprising a container for collecting liquid scattered from said semiconductor substrate.

5. The deposit removing apparatus according to claim 1, further comprising a mover for moving said chemical solution tube and said rinsing water tube.

6. The deposit removing apparatus according to claim 5, wherein a range of movement of said chemical solution tube caused by said mover includes at least a position in which said chemical solution discharged from said chemical solution tube reaches the plane surface center of said semiconductor substrate.

7. The deposit removing apparatus according to claim 5, wherein a range of movement of said rinsing water tube caused by said mover includes at least a position in which said water discharged from said rinsing water tube reaches the plane surface center of said semiconductor substrate.

8. The deposit removing apparatus according to claim 1, wherein a direction into which said chemical solution flows out from said chemical solution tube is sloping against a direction perpendicular to a front face of said semiconductor substrate.

9. The deposit removing apparatus according to claim 1, wherein a direction into which said water flows out from said rinsing water tube is sloping against a direction perpendicular to a front face of said semiconductor substrate.

10. A deposit removing method for deposited material on a semiconductor substrate during etching of a film formed on said semiconductor substrate, comprising the steps of:
supplying chemical solution on said semiconductor substrate to exfoliate said deposit from said semiconductor substrate;
scattering said chemical solution by rotating said semiconductor substrate; and
supplying water on said semiconductor substrate.

11. The deposit removing method according to claim 10, further comprising the step of scattering said water by rotating said semiconductor substrate after the step of supplying said water.

12. The deposit removing method according to claim 11, wherein the steps ranging from supplying said chemical solution to scattering said water by the rotation of said semiconductor substrate are repeatedly performed.

13. The deposit removing method according to claim 10, further comprising the steps of, before supplying said chemical solution:
supplying water on said semiconductor substrate; and
scattering said water by rotating said semiconductor substrate.

14. The deposit removing method according to claim 10, wherein in the step of supplying said chemical solution, the chemical solution is so supplied onto a position spaced from a plane surface center of said semiconductor substrate as that said chemical solution reaches at least the plane surface center of said semiconductor substrate.

15. The deposit removing method according to claim 14, wherein said chemical solution is supplied from a position shifted from the plane surface center of said semiconductor substrate into a direction sloping against a direction perpendicular to a front face of said semiconductor substrate.

16. The deposit removing method according to claim 10, wherein in the step of supplying said water, the water is so supplied onto a position spaced from a plane surface center of said semiconductor substrate as that said water reaches at least the plane surface center of said semiconductor substrate.

17. The deposit removing method according to claim 16, wherein said water is supplied from a position shifted from the plane surface center of said semiconductor substrate into a direction sloping against a direction perpendicular to a front face of said semiconductor substrate.

18. The deposit removing method according to claim 11, further comprising the step of drying said semiconductor substrate after the step of scattering said water by rotating said semiconductor substrate.

19. The deposit removing method according to claim 18, further comprising the step of further scattering said water by rotating said semiconductor substrate, between the step of scattering said water by rotating said semiconductor substrate and the step of drying said semiconductor substrate.

20. The deposit removing method according to claim 10, wherein a rotating axis of said semiconductor substrate used in the step of rotating said semiconductor substrate holds a direction perpendicular to a front face of said semiconductor substrate.
